(19) United States
(12) Patent Application Publication
(10) Pub. No.: US 2017/0146793 A1
(43) Pub. Date: May 25, 2017

(54) MICROFABRICATED OPTICAL APPARATUS WITH INTEGRATED TURNING SURFACE

(71) Applicant: Innovative Micro Technology, Goleta, CA (US)

(72) Inventors: Christopher S. GUDEMAN, Lompoc, CA (US); Sangwoo Kim, Santa Barbara, CA (US); Stuart Hutchinson, Murrieta, CA (US); Marin SIGURDSON, Goleta, CA (US)

(73) Assignee: Innovative Micro Technology, Goleta, CA (US)

(21) Appl. No.: 15/355,461

(22) Filed: Nov. 18, 2016

Related U.S. Application Data
(60) Provisional application No. 62/258,302, filed on Nov. 20, 2015.

(51) Int. Cl. G02B 26/08; G03F 7/26; G02B 1/11; G03F 7/20; B81B 3/00; B81C 1/00

(52) U.S. Cl. CPC G02B 26/0833; B81B 3/0083; B81C 1/00198; G02B 1/11; G03F 7/2006; G03F 7/2008; G03F 7/26; B81B 2201/042; B81B 2201/0292; B81C 2203/0109; B81C 2203/0145

(57) ABSTRACT

A microfabricated optical apparatus that includes a light source or light detector in combination with an integrated turning surface to form a microfabricated optical subassembly. The integrated turning surface may be formed directly in the substrate material using gray scale lithography.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to microfabricated optical subassemblies.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer. It should be understood that the lid wafer is optional, and that the device may do manufactured as a module, to be included as a subcomponent of another structure.

One such device that may be manufactured using MEMS techniques is an microfabricated optical table. Microfabricated optical tables may include very small optical components which may be arranged on the surface of a substrate in a manner analogous to a macroscopic optical components mounted on a full sized optical bench. These microfabricated components may include light sources such as light emitting diodes (LED's), beam shaping structures such as lenses and turning mirrors, and anti-relection devices such as Faraday rotators and optical isolators. After fabrication, these devices may be enclosed with a lid wafer to protect them in an encapsulated device cavity. Indeed, some devices, such as infrared detectors and emitters, may require a vacuum environment, such that the device cavity may need to be hermetically sealed. Laser diodes are notoriously sensitive to moisture, such that encapsulation is necessary to protect them from environmental sources of moisture.

In order to miniaturize such systems such as for optical communications systems, these systems may be made in a batch fashion on the surface of a silicon substrate. However, it remains an ongoing problem to manufacture and encapsulate these devices in a cost effective manner. Accordingly, microfabricated high frequency optical structures have posed an unresolved problem.

### SUMMARY

Prior art is shown in FIG. 1, where an edge emitting laser 1 is mounted on a Si substrate 7, which also supports a ball lens 2 and a Faraday rotator 3. The radiation from the laser is launched into the ball lens 2, where it is collimated. After passing through the Faraday rotator 3, it is reflected off of an anisotropically etched facet 5 in the lid and routed through the substrate at a non-normal angle. Anti-reflection coatings are employed on all interfaces along the radiation path. Note that the facet on the lid is necessarily 54.7°. This can be an unacceptable constraint in some architectures.

We describe a wafer level packaging architecture that eliminates the ball lens 2, the Faraday rotator 3 and the turning mirror 5. Furthermore, it permits the die size to be reduced by roughly 50%, which can drastically reduce cost. Size reduction in all three dimensions is possible. Additionally, the exiting beam of light can be directed at virtually any angle with respect to the originating beam. Also, the achromatic performance of the reflective optics is suitable for multi-wavelength application. Finally, the number of interfaces, each of which will create unwanted parasitic reflections, that the beam traverses is reduced. We also describe an architecture that incorporates Through Substrate Vias (TSVs), which provide a high low loss electrical pathway for laser modulation. The TSVs also enable the optical path and the electrical path to be on the same or opposite surfaces.

The architecture makes use of gray scale lithography to form the integrated turning surface directly on a wall of the enclosure. The surface may be, for example, elliptical or off-axis paraboloid, for example. The surface may be made in the lid substrate, or in the lower device substrate, or in another additional piece of substrate material. The mirror may collimate, focus, and/or redirect the radiation out of the cavity through the lid substrate or the device substrate, or through a side wall.

Accordingly, a microfabricated optical apparatus may be fabricated on a substrate and enclosed in a device cavity, and the apparatus may include at least one of a light source and a light detector, and an integrated turning surface which redirects the beam of light, wherein the integrated turning surface is defined by a contoured surface of the silicon substrate.

These and other features and advantages are described in, or are apparent from, the following detailed description.

### BRIEF DESCRIPTION OF THE DRAWINGS

Various exemplary details are described with reference to the following figures, wherein:

FIG. 1 is a schematic illustration of a prior art microfabricated optical apparatus;

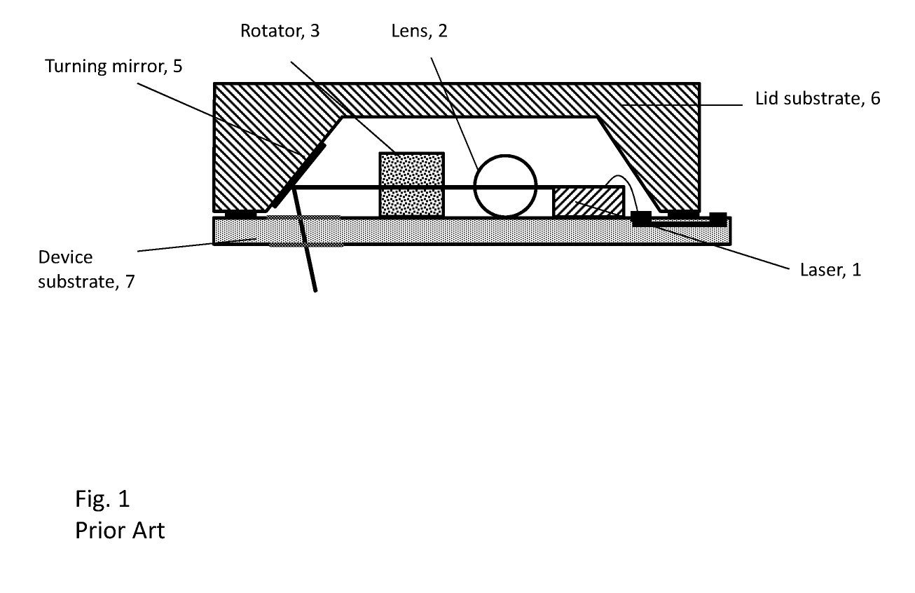

FIG. 2 is a schematic, cross sectional illustration of a first embodiment of a microfabricated optical apparatus with integrated off-axis lens;

FIGS. 3a-3d are diagrams of an exemplary process to make the integrated, off-axis lens;

FIG. 4 illustrates a second embodiment of a microfabricated optical apparatus with integrated, off-axis lens;

FIG. 5 illustrates a third embodiment of a microfabricated optical apparatus with integrated, off-axis lens;

FIG. 6 illustrates a fourth embodiment of a microfabricated optical apparatus with integrated, off-axis lens;

FIG. 7 illustrates a fifth embodiment of a microfabricated optical apparatus with integrated, off-axis lens; and

FIG. 8 illustrates a sixth embodiment of a microfabricated optical apparatus with integrated, off-axis lens;

FIG. 9 illustrates the behavior of an elliptical mirror; and

FIG. 10 illustrates the behavior of an off-axis parabolic mirror.

### DETAILED DESCRIPTION

For high speed optical data communication radiation from infrared lasers is amplitude and/or frequency modulated with data and launched on an optical fiber. The quality of the laser beam and the reliability of the laser are critical to high fidelity data transmission. VCSEL technology provides a highly reliable laser, but the beam quality is inferior to that of an edge emitting laser. The latter, however, has poor lifetime (reliability) unless packaged hermetically. Recent advances in laser packaging has enabled the edge emitting laser approach, but the complexity of assembly and the parts-count that are assembled into the hermetic package result in a high cost, low yield, and difficult alignment processes during assembly. We describe here a method to simplify the hermetic package for edge emitting laser and this improve upon the cost, yield and assembly issues. Note that the method described here can also be applied to VCSEL technology, thus providing similar benefit in the performance and manufacturing of systems using VCSELs.

Additionally, the edge emitting laser provides radiation in a direction that is orthogonal to that desired for many transmitting optical subassembly (TOSA) architectures. The method described here provides a means to turn the direction of propagation. This can be used for VCSELs as well.

As mentioned previously, a method for making complex curves lithographically may be used to make an ellipsoidal or parabolic mirror, or any other complex shape, directly on a wall of the device cavity or a surface of a device substrate. The complex shape may then be coated with a layer of gold or other highly reflective material to make a microfabricated optical apparatus with integrated turning surface.

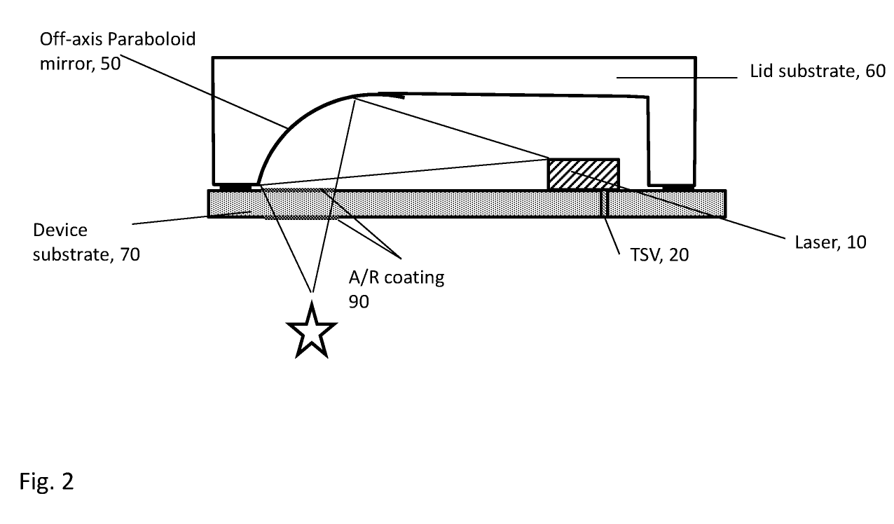

A first embodiment is shown in FIG. 2. A laser or light source 10 is mounted on a Si substrate 70 with the emitting facet up. The light source may be a light emitting diode, a laser diode, an edge emitting laser diode, a laser diode, or a vertical cavity surface emitting laser, for example.

The light source 10 may be modulated and driven by a signal that is delivered from below by a through substrate via 70. The through substrate via 70 is described more fully in U.S. patent application Ser. No. ______. The diverging light from the laser 10 may be captured on a curved integrated turning surface 50 on silicon lid substrate 60. The integrated turning surface may both collimate and focus, as well as turns the optical radiation, thus routing the radiation through the Si substrate 70. Silicon is transparent at near infrared wavelengths, where most optical communication systems operate. The lid substrate may be bonded to the device substrate to encapsulate the optical apparatus in a substantially hermetic device cavity. The bonding technique may be, for example, a low temperature metal alloy bond or a thermocompression bond.

This curved integrated turning surface 50 may be an off-axis paraboloid (OAP) or an elliptical mirror (EM), which can be etched into the Si lid using a gray-scale lithography technique described below. One of skill in the art will recognize that any other complex shape may similarly be formed. Since the mirror may be etched directly onto the surface of the substrate material, it is referred to herein as an “integrated optical component” or “integrated turning surface,” meaning that the component is formed directly on, or directly from, substrate material.

In this gray scale technique, photoresist is patterned to form a curved surface that closely resembles the desired shape of the curved mirror. During the etch, which can be carried out using a dry vacuum process using SF6, CF4, C4F8, or other gases that readily etch Si, the photoresist is also eroded or etched gradually leaving more and more of the Si exposed to the etching gas as the thin edges of the photoresist etch away. The exposed Si then begins to etch in the newly exposed areas. This is carried out until the photoresist is completely removed and its original shape has been transferred into the silicon lid substrate 60.

In FIG. 2, the function of the ball lens 2 and the turning mirror 5 are now provided by the integrated turning surface 50, so that these components may be eliminated. The Faraday rotator as used in the prior art functions in combination with an external quarter-wave plate to provide immunity to parasitic reflections, which can disrupt the laser stability. Thus, it can be eliminated or moved outside of the package since the primary reflecting surfaces of the prior art are eliminated in the preferred embodiment shown in FIG. 2. The final shape is then coated with Au or another highly reflective material to provide a low loss optical path.

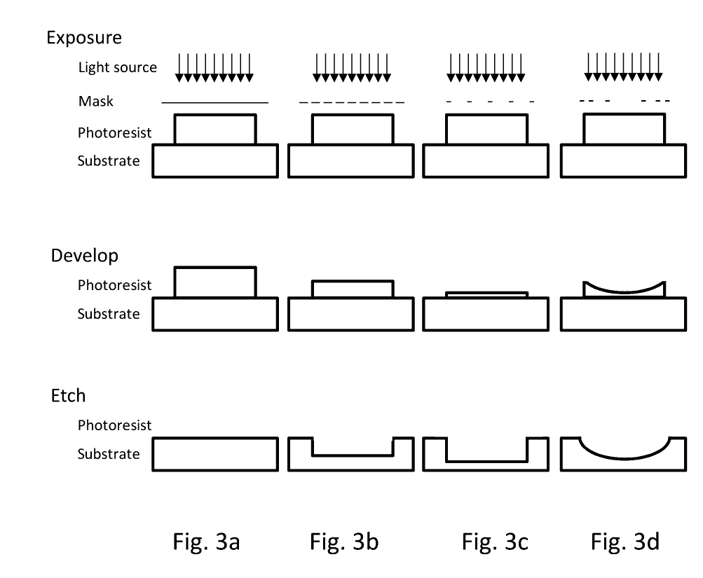

A diagram of this process is shown in FIG. 3. FIG. 3 shows a light source irradiating a photoresist layer through a mask with holes of varying size and pitch. In FIG. 3a, there are no holes in the mask, such that no light is transmitted, and the photoresist is not exposed or developed. As a result, the substrate is not etched. In FIG. 3b, the holes are narrow and few, such that not much light penetrates and exposes the photoresist. In FIG. 3b, the holes are larger, such that more light penetrates and a deeper feature is etched. In FIG. 3d, the holes vary in pitch across the width of the feature. More light is transmitted at the center than at the edges, so a curved feature is etched in the substrate. Using the technique illustrated schematically in FIG. 3d, the ellipsoidal or off axis parabolic mirror 50 may be fabricated. The complex shape created by this process may then be coated with a layer of gold or other highly reflective material to make a microfabricated optical apparatus with integrated mirror. The reflective layer may be deposited by, for example, vapor deposition or sputtering.

Because the radiation emission profile of an edge emitting laser has a greater divergence along one axis as compared to the orthogonal axis, the ability to create arbitrary shapes allows for a creation of a anisotropic mirror, which has a different focal length along one axis as compared to the other. This results in an improved beam shape.

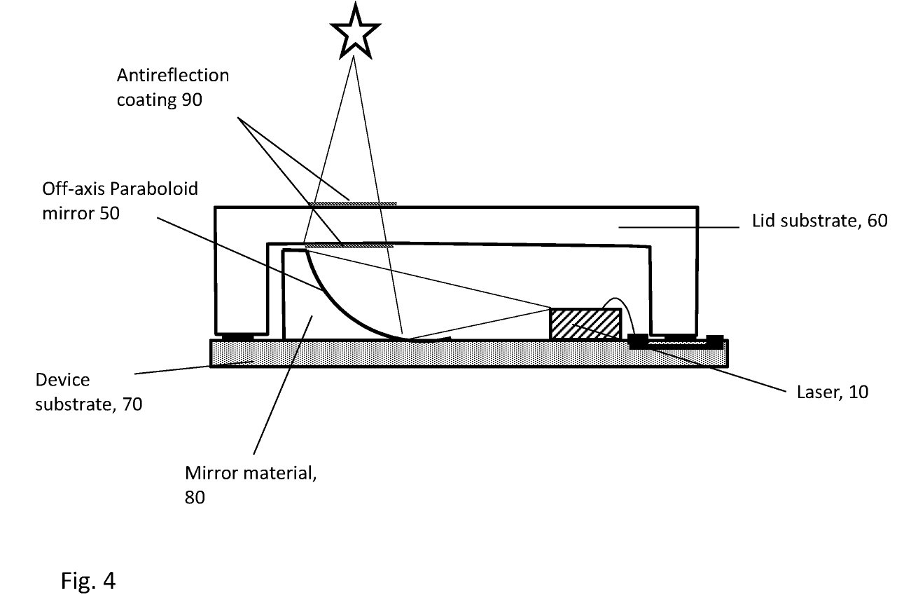

FIG. 4 shows a second embodiment, where the laser radiation is routed up through the lid substrate. Through silicon vias (TSVs) may or may not be needed. As in FIG. 2, diverging light from the laser 10 is captured on a curved integrated turning surface 50 which may now be formed on a separate piece of substrate material and may direct the radiation up through silicon lid substrate 60. Two antireflection coatings 90 on silicon lid substrate 60 may reduce or minimize back reflections. The curved integrated turning surface 50 may both collimate and focus, as well as turn or redirect the optical radiation. The radiation may thus be routed through the silicon lid substrate 60, which is transparent at near infrared wavelengths, where most optical communication systems operate. This curved integrated turning surface 50 may be an off-axis paraboloid (OAP) or an elliptical mirror (EM), which can be etched into the Si lid using a gray-scale lithography technique described above.

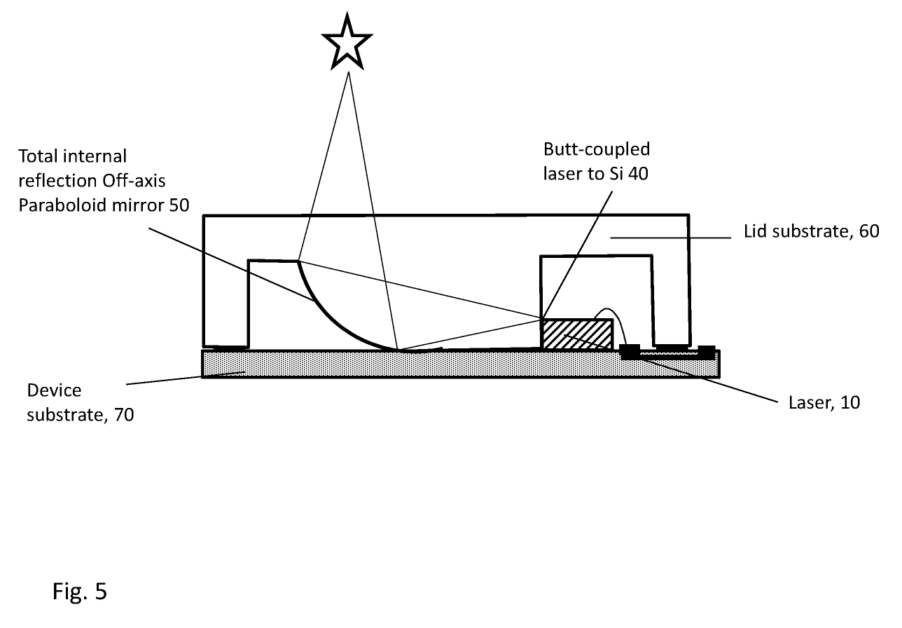

FIG. 5 shows an embodiment that may route the laser radiation through the lid substrate, but this time the radiation may be coupled directly from the laser 10 facet to the silicon lid substrate 60 by butt-coupling the laser 10 to a vertical surface in the lid substrate 60 using an index matching adhesive. Total internal reflection of the light at the Si/air interface may provide an excellent reflector inside of the silicon lid substrate 60.

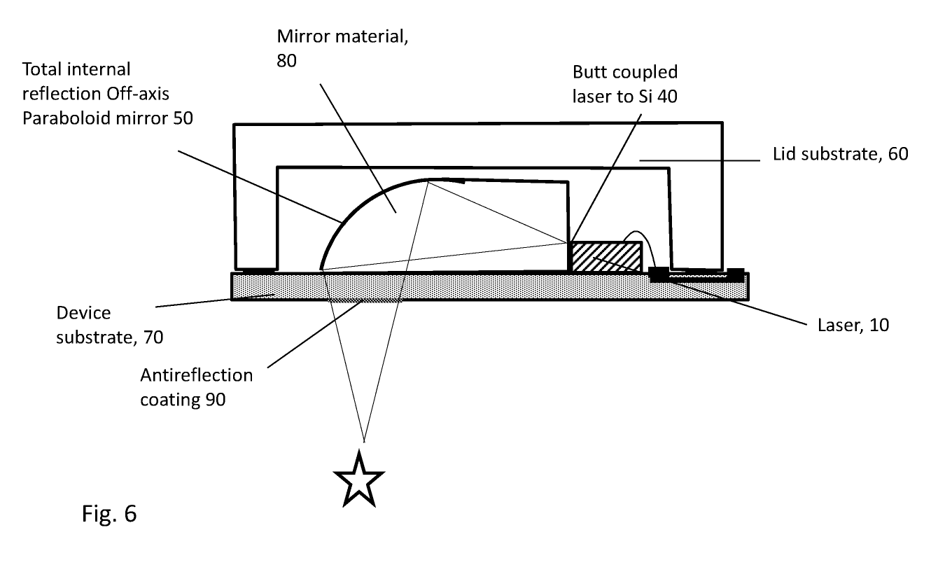

FIG. 6 shows a butt-coupling method that routes the radiation through the lower silicon device substrate 70. In this embodiment, the integrated turning surface 50 may be formed on a separate piece of material 80. The reflection of the radiation is by total internal reflection at the air/silicon boundary.

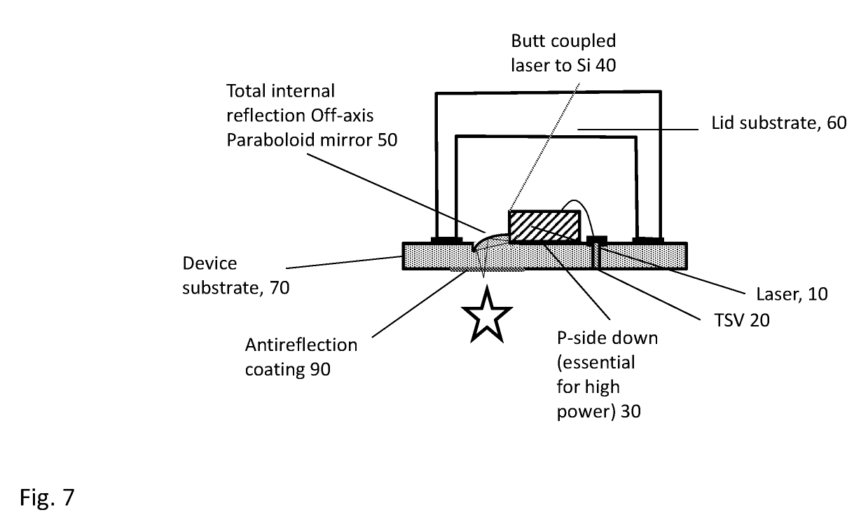

FIG. 7 shows another embodiment that employs butt-coupling, but in this case the laser is mounted with the facet surface (p-side) down so that it is contact with the silicon substrate 70. This is preferred because it provides for better heat dissipation, which improves the laser life and stability, and allows for higher power output. In this embodiment, the integrated turning surface 50 is formed in the silicon device substrate 70. The radiation may exit the device through an antireflection coating 90 applied to the underside of the silicon device substrate 70. Note that the die can be drastically reduced in size, thus reducing cost.

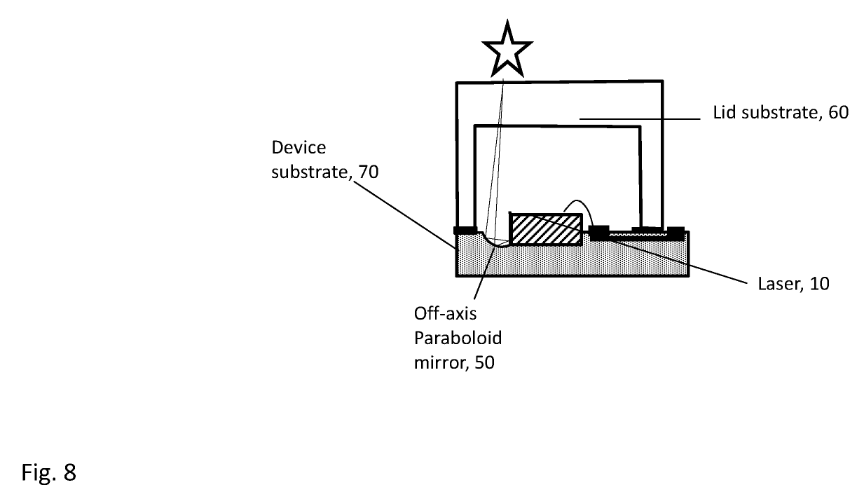

Another embodiment is shown in FIG. 8. Note that the laser radiation propagates in free space in this case and that the p-side is down for good thermal conductivity. In this embodiment, the integrated turning surface 50 is again formed in the silicon device substrate 70, but is shaped to direct the radiation upward through the lid substrate 60. Again, the device size may be drastically reduced. TSVs may or may not be used.

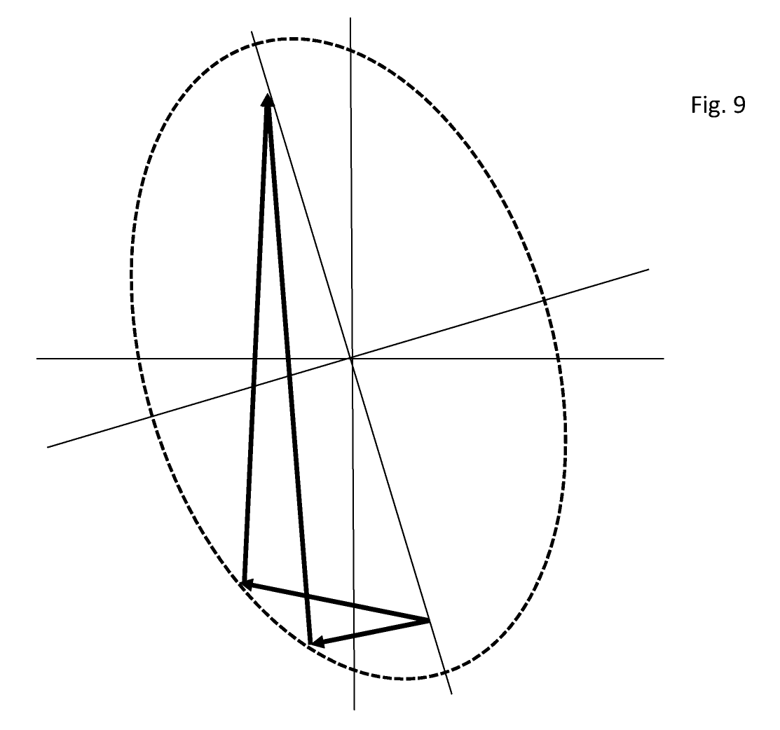

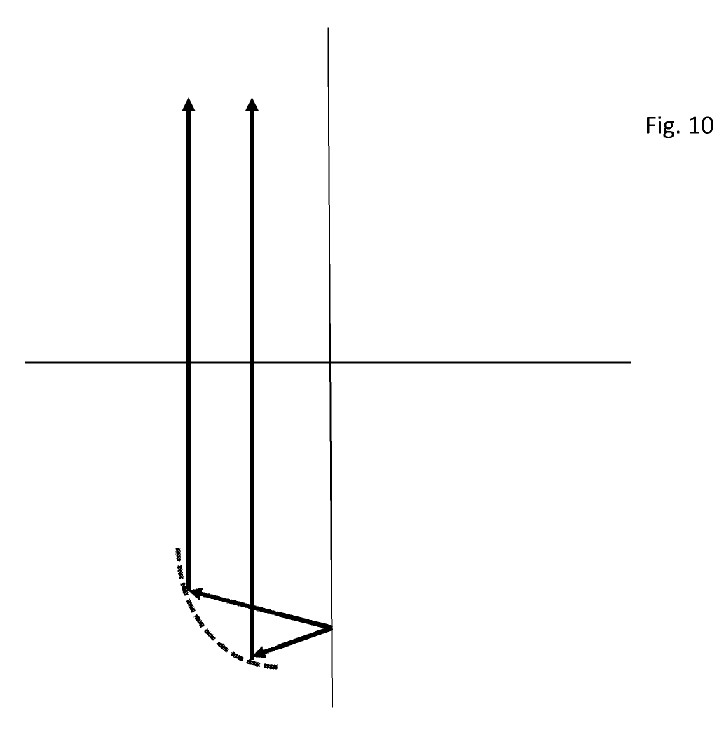

FIG. 9 and FIG. 10 respectively illustrate an elliptical mirror (EM, FIG. 9) and an off-axis paraboloid (OAP, FIG. 10). The EM of FIG. 9 may focus a light source located at one focus of the ellipsoid to the other focus of the ellipsoid. The OAP shown in FIG. 10 may collimate diverging light source located at the focus of the paraboloid. The specific shape, such as OAP or EM, may be chosen to best match the receiving part of the system.

While the aforementioned embodiments are described with respect to a transmitting optical subassembly (TOSA), it should be understood that the systems and techniques described herein may alternatively be applied to a receiving optical subassembly (ROSA). Indeed, by the substitution of an optical detector in the place of the light source 10, an integrated ROSA may be realized.

Accordingly, disclosed here is a microfabricated optical apparatus fabricated on a silicon substrate and enclosed in a device cavity. The optical apparatus may include at least one of a light source and a light detector, and an integrated turning surface which redirects the beam of light, wherein the integrated turning surface is defined by a contoured surface of the silicon substrate. The apparatus may further comprise a lid substrate with the device cavity formed therein, and coupled to a device substrate, wherein the device cavity encapsulates the optical apparatus. A signal may be applied to the light source, and that signal is a direct current electrical signal which is applied to a through silicon via which extends through a thickness of the device substrate. The apparatus may further comprise a device which modulates at least one of a frequency, an amplitude, and a phase, to encode the optical radiation emitted from the light source with an information signal. The integrated turning surface may focus the beam of light, and further comprise at least one antireflective coating disposed on at least on wall of the device cavity. The light source may be at least one of a light emitting diode, a laser diode, an edge emitting laser diode, a laser diode, and a vertical cavity surface emitting laser. The integrated turning surface may be an optical reflector that reflects radiation by total internal reflection. The optical radiation may exit the device cavity through a roof of the lid substrate, or through the device substrate. The device cavity may encapsulate a plurality of light sources. The integrated turning surface be may one of an off axis paraboloid and an elliptical mirror, and may include a reflective film deposited on a curved surface of the integrated turning surface, or it may be a reflective film deposited on an inclined surface of an optical element located within the device cavity.

A method for fabricating an optical apparatus on a substrate is also disclosed, which may include forming a device cavity in a lid wafer, forming an integrated turning surface on a surface of the silicon substrate, disposing at least one of a light source or a light detector in the device cavity, bonding the substrate to the lid wafer to encapsulate the optical apparatus in a substantially hermetic device cavity. The integrated turning surface may comprise etching the integrated turning surface using gray scale lithography. Bonding the substrate to the lid wafer may comprise bonding the substrate to the lid wafer with a low temperature metal alloy bond or a thermocompression bond. Forming an integrated turning surface on a surface of the silicon substrate may comprise forming a surface which redirects the light using total internal reflection. The method may include depositing a reflective coating on the integrated turning surface, and forming at least one antireflective layer on at least one wall of the device cavity.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Furthermore, details related to the specific methods, dimensions, materials uses, shapes, fabrication techniques, etc. are intended to be illustrative only, and the invention is not limited to such embodiments. Descriptors such as top, bottom, left, right, back front, etc. are arbitrary, as it should be understood that the systems and methods may be performed in any orientation. Accordingly, the exemplary implementations set forth above, are intended to be illustrative, not limiting.

What is claimed is:

1. A microfabricated optical apparatus fabricated on a silicon substrate and enclosed in a device cavity, comprising:
at least one of a light source and a light detector; and
an integrated turning surface which redirects the beam of light;
wherein the integrated turning surface is defined by a contoured surface of the silicon substrate.

2. The microfabricated optical apparatus of claim 1, further comprising a lid substrate with the device cavity formed therein, and coupled to a device substrate, wherein the device cavity encapsulates the optical apparatus.

3. The microfabricated optical apparatus of claim 2, wherein a signal is applied to the light source, and that signal is a direct current electrical signal which is applied to a through silicon via which extends through a thickness of the device substrate.

4. The microfabricated optical apparatus of claim 1, further comprising: a device which modulates at least one of a frequency, an amplitude, and a phase, to encode the optical radiation emitted from the light source with an information signal.

5. The microfabricated optical apparatus of claim 1, wherein the integrated turning surface focuses the beam of light.

6. The microfabricated optical apparatus of claim 2, further comprising at least one antireflective coating disposed on at least on wall of the device cavity.

7. The microfabricated optical apparatus of claim 1, wherein the light source is at least one of a light emitting diode, a laser diode, an edge emitting laser diode, a laser diode, and a vertical cavity surface emitting laser.

8. The microfabricated optical apparatus of claim 1, wherein the integrated turning surface is an optical reflector that reflects radiation by total internal reflection.

9. The microfabricated optical apparatus of claim 2, wherein the optical radiation exits the device cavity through a roof of the lid substrate.

10. The microfabricated optical apparatus of claim 2, wherein the optical radiation exits the device cavity through the device substrate.

11. The microfabricated optical apparatus of claim 2, wherein the device cavity encapsulates a plurality of light sources.

12. The microfabricated optical apparatus of claim 1, wherein the integrated turning surface is one of an off axis paraboloid and an elliptical mirror.

13. The microfabricated optical apparatus of claim 2, wherein the integrated turning surface includes a reflective film deposited on a curved surface of the integrated turning surface.

14. The microfabricated optical apparatus of claim 1, wherein the turning surface is a reflective film deposited on an inclined surface of an optical element located within the device cavity.

15. A method for fabricating an optical apparatus on a substrate, comprising:
forming a device cavity in a lid wafer;
forming an integrated turning surface on a surface of the silicon substrate;
disposing at least one of a light source or a light detector in the device cavity;
bonding the substrate to the lid wafer to encapsulate the optical apparatus in a substantially hermetic device cavity.

16. The method of claim 13, wherein forming the integrated turning surface comprises etching the integrated turning surface using gray scale lithography.

17. The method of claim 13, wherein bonding the substrate to the lid wafer comprises bonding the substrate to the lid wafer with a low temperature metal alloy bond or a thermocompression bond.

18. The method of claim 13, wherein forming an integrated turning surface on a surface of the silicon substrate comprises forming a surface which redirects the light using total internal reflection.

19. The method of claim 13, further comprising:
depositing a reflective coating on the integrated turning surface.

20. The method of claim 13, further comprising:
forming at least one antireflective layer on at least one wall of the device cavity.
